(19) United States
(12) Patent Application Publication
(10) Pub. No.: US 2010/0283059 A1
(43) Pub. Date: Nov. 11, 2010

(54) SEMICONDUCTOR DEVICE AND METHOD FOR MANUFACTURING SAME

(76) Inventors: Makoto Nakazawa, Osaka (JP); Tomohiro Kimura, Osaka (JP)

Correspondence Address: BIRCH STEWART KOLASCH & BIRCH, PO BOX 747, FALLS CHURCH, VA, 22040-0747, US

(21) Appl. No.: 12/811,842

(22) PCT Filed: Dec. 25, 2008
(86) PCT No.: PCT/JP2008/003973

§ 371 Date: Jul. 7, 2010

(30) Foreign Application Priority Data
Apr. 8, 2008 (JP) 2008 100650

(51) Int. Cl. H01L 29/786; H01L 21/336; H01L 21/84; H01L 23/552

(52) U.S. Cl. 257/66; 438/149; 438/479; 257/659; 257/E23.114; 257/E29.292; 257/E21.412; 257/E21.704

(57) ABSTRACT

A semiconductor device includes: an insulating substrate; a stepwise layer arranged on the insulating substrate and having an end portion whose inclination angle is equal to or greater than 60°; an insulating layer formed on the insulating substrate and the stepwise layer so as to be elevated on the stepwise layer; a first semiconductor layer arranged at a portion adjacent to the elevated insulating layer; and a second semiconductor layer structured with a material identical to that of the first semiconductor layer, and formed in an island shape on the elevated insulating layer.

### TECHNICAL FIELD

The present invention relates to a semiconductor device that is applied to a liquid crystal display device, for example, of an active matrix type, and the like, and a method for manufacturing the same.

### BACKGROUND ART

Generally, an active-matrix type display device includes an insulating substrate such as a glass substrate, on which a plurality of pixel regions are disposed in a matrix pattern, at which thin film transistors are respectively formed.

A formation method of the thin film transistors is as follows. First, on an insulating substrate, an insulation film such as a silicon oxide film, a silicon nitride film or the like is formed. After an amorphous silicon layer is formed thereon, the structure is subjected to laser beam radiation, so as to be crystallized into a polysilicon layer. Next, the polysilicon layer is etched into a pattern of a plurality of islands that structure a matrix. The polysilicon layer patterned into island shapes is further subjected to a prescribed processing, and thereby the thin film transistors are formed.

As a formation method of the thin film transistors, PATENT DOCUMENT 1 discloses a manufacturing method of a semiconductor device, which includes the steps of: forming a light shielding layer and a buffer film partially on a substrate, and forming an amorphous silicon layer over the entire buffer film; performing a laser annealing to the amorphous silicon layer, so as to form a polysilicon layer; and patterning the polysilicon layer into a pattern that is substantially identical to that of the light shielding layer.

### Citation List

### Patent Document

PATENT DOCUMENT 1: Japanese Patent Publication No. 2007-201076

### SUMMARY OF THE INVENTION

### Technical Problem

However, the patterning of the silicon layer in forming the thin film transistors involves various problems.

FIG. 18 is a schematic plan view of an active matrix substrate 100 provided with thin film transistors 117 and 118 for use in a general active-matrix type display device. The active matrix substrate 100 is provided with the thin film transistors 117 and 118 on an insulating substrate 111. The thin film transistors 117 and 118 each have a patterned silicon layer 114. Formed respectively on the silicon layers 114 are gate electrodes 119 and 120, drain electrodes 121 and 123 and source electrodes 122 and 124, the drain electrodes 121 and 123 and the source electrodes 122 and 124 being electrically connected to the silicon layers 114 through contact holes 125 to 128.

Here, generally, the silicon layers 114 are patterned by photolithography or the like. After they are patterned by photolithography or the like, a residue 114′ of the silicon layer may possibly be generated between the adjacent silicon layers 114. This poses a problem of occurrence of a leak fault between the thin film transistors 117 and 118.

Further, in a case where a light shielding layer is arranged beneath each of the thin film transistors 117 and 118, it is difficult to carry out patterning such that the silicon layers 114 of the thin film transistors 117 and 118 are accurately located at the desired position. Hence, the size of the light shielding layer must be designed to be greater than that of the silicon layer more than actually needed, taking into account of a certain degree of misalignment. This poses a problem of a reduction in the aperture ratio of device.

The present invention has been made in consideration of the problems described above, and its object is to provide a semiconductor device and a method for manufacturing the same, with which a semiconductor layer can accurately be patterned without using photolithography.

### Solution to the Problem

A semiconductor device in accordance with the present invention includes: an insulating substrate; a stepwise layer arranged on the insulating substrate and having an end portion whose inclination angle is equal to or greater than 60°; an insulating layer formed on the insulating substrate and the stepwise layer so as to be elevated on the stepwise layer; a first semiconductor layer arranged at a portion adjacent to the elevated insulating layer; and a second semiconductor layer structured with a material identical to a material of the first semiconductor layer, and formed in an island shape on the elevated insulating layer.

In the semiconductor device in accordance with the present invention, the insulating layer may have a thickness of equal to or greater than 20 nm and equal to or smaller than 200 nm.

Further, in the semiconductor device in accordance with the present invention, the stepwise layer may be a light shielding layer.

Still further, in the semiconductor device in accordance with the present invention, the light shielding layer may have a thickness of equal to or greater than 50 nm.

A semiconductor device in accordance with the present invention includes: an insulating substrate; a base coat layer arranged on the insulating substrate; stepwise layer arranged on the base coat layer and having an end portion whose inclination angle is equal to or greater than 60°; a first semiconductor layer arranged on the base coat layer and at a portion adjacent to the stepwise layer; and a second semiconductor layer structured with a material identical to a material of the first semiconductor layer, and formed in an island shape, on the stepwise layer.

In the semiconductor device in accordance with the present invention, the first semiconductor layer may be provided at least two in number so as to be disposed adjacent to each other, each of the first semiconductor layers being an active layer of a thin film transistor; and the second semiconductor layer may be arranged between the adjacent first semiconductor layers.

Still further, in the semiconductor device in accordance with the present invention, the second semiconductor layer may structure an active layer of a thin film transistor.

A method for manufacturing a semiconductor device in accordance with the present invention includes: a stepwise layer formation step of forming a stepwise layer having an end portion whose inclination angle is equal to or greater than 60° on an insulating substrate; an insulating layer formation step of forming an insulating layer on the insulating substrate and the stepwise layer so as to be elevated on the stepwise layer; a semiconductor layer formation step of forming a semiconductor layer on the insulating layer formed on the insulating substrate and the stepwise layer; and a step-caused disconnection formation step of irradiating the semiconductor layer with a laser beam so as to crystallize the semiconductor layer and to form a step-caused disconnection at the semiconductor layer at a portion corresponding to the end portion of the stepwise layer, thereby forming a first semiconductor layer at a portion adjacent to the elevated insulating layer, and an island-shaped second semiconductor layer on the elevated insulating layer.

In the method for manufacturing a semiconductor device in accordance with the present invention, in the insulating layer formation step, the insulating layer may be formed to have a thickness of equal to or greater than 20 nm and equal to or smaller than 200 nm.

Further, in the method for manufacturing a semiconductor device in accordance with the present invention, the stepwise layer may be a light shielding layer.

Still further, in the method for manufacturing a semiconductor device in accordance with the present invention, the light shielding layer may be formed to have a thickness of equal to or greater than 50 nm.

A method for manufacturing a semiconductor device in accordance with the present invention includes: a stepwise layer formation step of forming a stepwise layer having an end portion whose inclination angle is equal to or greater than 60° on a base coat layer, the base coat layer being formed on a surface of an insulating substrate; a semiconductor layer formation step of forming a semiconductor layer on the base coat layer and the stepwise layer so as to be elevated on the stepwise layer; and a step-caused disconnection formation step of irradiating the semiconductor layer with a laser beam so as to crystallize the semiconductor layer and to form a step-caused disconnection at the semiconductor layer at a portion corresponding to the end portion of the stepwise layer, thereby forming a first semiconductor layer at a portion adjacent to the stepwise layer, and an island-shaped second semiconductor layer on the stepwise layer.

In the method for manufacturing a semiconductor device in accordance with the present invention, the first semiconductor layer formed in the step-caused disconnection formation step may be used as an active layer to form a thin film transistor.

Further, in the method for manufacturing a semiconductor device in accordance with the present invention, the second semiconductor layer formed in the step-caused disconnection formation step may be used as an active layer to form a thin film transistor.

### ADVANTAGES OF THE INVENTION

The present invention can provide a semiconductor device a manufacturing the same, with which a semiconductor layer can accurately be patterned without using photolithography.

### BRIEF DESCRIPTION OF THE DRAWINGS

FIG. 1 is a plan view of an active matrix substrate of a semiconductor device in accordance with a first embodiment.

FIG. 2 is a cross-sectional view taken along line I-I′ in FIG. 1.

FIG. 3 is a cross-sectional view of an insulating substrate at which an amorphous silicon thin film is formed in accordance with the first embodiment.

FIG. 4 is a cross-sectional view of the insulating substrate at which gate electrodes are formed in accordance with the first embodiment.

FIG. 5 is a cross-sectional view of a semiconductor device in accordance with another mode of the first embodiment.

FIG. 6 is a cross-sectional view of an insulating layer and a silicon thin film formed on a light shielding layer whose end portions each have an inclination angle of smaller than 60°.

FIG. 7 is a plan view of an active matrix substrate of a semiconductor device in accordance with a second embodiment.

FIG. 8 is a cross-sectional view taken along line II-II′ in FIG. 7.

FIG. 9 is a cross-sectional view of an insulating substrate provided with an amorphous silicon thin film in accordance with the second embodiment.

FIG. 10 is a cross-sectional view of the insulating substrate shown in FIG. 9 in a state where the silicon thin film is crystallized hereby step-caused disconnections occur.

FIG. 11 is a plan view of a silicon thin film in which a mask is arranged at a gate electrode formation region, in a manufacturing step of an N channel type polycrystalline silicon thin film transistor.

FIG. 12 is a plan view of a silicon thin film in which a mask is arranged at a gate electrode formation region and on an island-shaped first semiconductor layer, in a manufacturing step of a P channel type polycrystalline silicon thin film transistor.

FIG. 13 is a plan view of a silicon thin film in which a mask is arranged at a gate electrode formation region and on an island-shaped first semiconductor layer, in a manufacturing step of an N channel type polycrystalline silicon thin film transistor.

FIG. 14 is a plan view of a silicon thin film in which a mask is arranged at a gate electrode formation region, in a manufacturing step of a P channel type polycrystalline silicon thin film transistor.

FIG. 15 is a plan view of an N channel type polycrystalline silicon thin film transistor.

FIG. 16 is a plan view of a P channel type polycrystalline silicon thin film transistor.

FIG. 17 is a cross-sectional view of a semiconductor device in accordance with another mode of the second embodiment.

FIG. 18 is a plan view of an active matrix substrate of a semiconductor device of a conventional type.

### DESCRIPTION OF EMBODIMENTS

In the following, the structure and the manufacturing method of a semiconductor device in accordance with the present invention will be described in detail, referring to the drawings. Note that the present invention is not limited to the following embodiments.

### First Embodiment

### (Structure of Semiconductor Device 10)

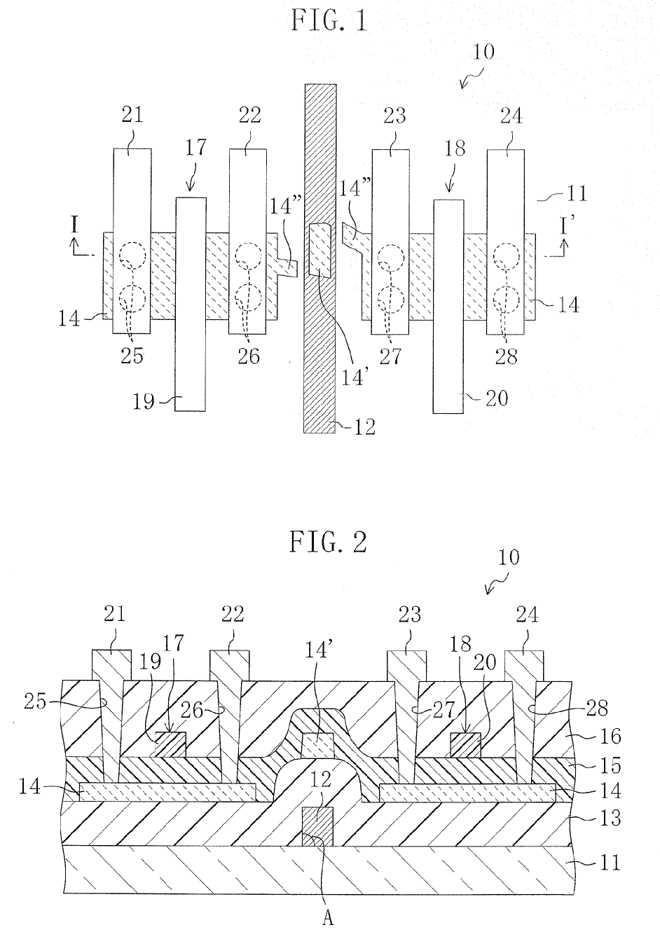

FIG. 1 is a schematic plan view of an active matrix substrate of semiconductor device 10 in accordance with a first embodiment of the present invention. FIG. 2 is a cross-sectional view taken along line I-I′ in FIG. 1.

The semiconductor device 10 includes the active matrix substrate shown FIGS. 1 and 2. The active matrix substrate includes an insulating substrate 11 such as a glass substrate. On the insulating substrate 11, a stepwise layer 12 is formed to extend between first semiconductor layers 14 in respective pixel regions that are disposed in a matrix pattern. The component material of the stepwise layer 12 is not specifically limited, and the stepwise layer 12 may be formed as a light shielding layer using a material possessing a light-shielding property. Preferably, a specific component material of the stepwise layer 12 is, for example, a metal material with high melting point such as tungsten, tantalum, molybdenum or the like, or a material that exhibits high workability, such as SiN, SiO₂ or the like. An inclination angle A of each end portion of the stepwise layer 12 is formed to be approximately 90°. Here, the inclination angle A of equal to or greater than 60° suffices for each end portion of the stepwise layer 12. For example, each end portion of the stepwise layer 12 may be greater than 90°. In other words, each end portion of the stepwise layer 12 may be formed in an inverse tapered shape.

On the insulating substrate 11 and the stepwise layer 12, an insulating layer 13 is formed. The insulating layer 13 is formed to have a thickness of equal to or greater than 20 nm and equal to or smaller than 200 nm, and arranged to be elevated on the stepwise layer 12. The insulating layer 13 is structured with, for example, an SiO₂ layer, an SiNO layer or the like, and functions as an insulating member in a case where the stepwise layer 12 is formed by a conductive material, and as a base coat between the insulating substrate such as glass and the semiconductor layers of the thin film transistors. On the insulating layer 13, thin film transistors 17 and 18 are formed. The thin film transistors 17 and 18 each function as switching element of corresponding pixel region, and respectively include the first semiconductor layers 14 each having an active layer, and gate electrodes 19 and 20 respectively formed on the first semiconductor layers 14 having a gate insulating film 15 interposed therebetween. Each active layer includes a channel region, and a source region and a drain region arranged on opposite sides of the channel region.

The first semiconductor layers 14 are each structured with polycrystalline silicon, and arranged at a portion adjacent to a portion of the insulating layer 13 elevated on the stepwise layer 12. The first semiconductor layers 14 are disposed to be adjacent to each other, and respectively structure the active layers of the thin film transistors 17 and 18.

At the elevated portion of the insulating layer 13 between the adjacent first semiconductor layers 14, an island-shaped second semiconductor layer 14′ is arranged. The second semiconductor layer 14′ is structured with a material identical to that of the first semiconductor layer 14, that is, with polycrystalline silicon.

On the thin film transistors 17 and 18, an interlayer insulating film 16 is formed. At the interlayer insulating film 16 and the gate insulating film 15, contact holes 25 to 28 that reach the source region and the drain region of the active layer of each of the thin film transistors 17 and 18 are formed. The contact holes 25 and 27 that reach the source regions of the active layers and the contact holes 26 and 28 that reach the drain regions of the active layers are each filled with a conductive material, thereby structuring source electrodes 21 and 23 and drain electrodes 22 and 24, respectively.

The semiconductor device 10 includes the active matrix substrate structured as described above, and additionally provided with a display medium layer and the like. In this manner, the semiconductor device 10 structures, for example, a display device such as a liquid crystal display device, an organic/inorganic EL display device and the like.

### (Manufacturing Method of Semiconductor Device 10)

Next, a manufacturing method of the semiconductor device 10 in accordance with the first embodiment of the present invention will be described.

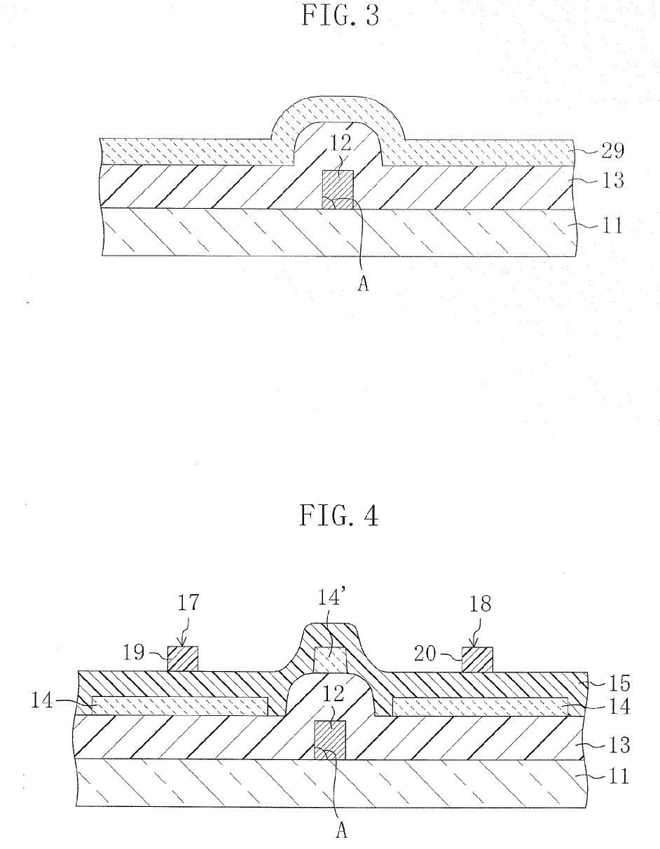

First, as shown in FIG. 3, an insulating substrate 11 such as a glass substrate is prepared. On the insulating substrate 11, a light-shielding material is deposited, which is structured with a high melting point metal such as Mo, for example. Subsequently, by etching the light-shielding material, a stepwise layer 12 having, for example, a thickness of equal to or greater than 50 nm and end portions each having an inclination angle A of 90°, so as to extend between regions corresponding to the thin film transistors 17 and 18.

Next, on the insulating substrate 11 and the stepwise layer 12, an insulating layer 13 having a thickness of equal to or greater than 20 nm and equal to or smaller than 200 nm is formed. Here, the insulating layer 13 is formed so as to be elevated on the stepwise layer 12 relative to the other portion.

Subsequently, on the insulating layer 13 formed on the insulating substrate 11 and the stepwise layer 12, an amorphous silicon thin film 29 is formed.

Next, the amorphous silicon thin film 29 is subjected to a laser crystallization process. In carrying out the laser crystallization process, a not-shown laser crystallization device is used. The laser crystallization device is structured, for example, with a pulsed laser oscillator, a mirror, an optical system, a work stage, a system controller, and the like.

The laser beam as used herein is, for example, an excimer laser beam having a wavelength of equal to or smaller than 400 nm, which is emitted such that the energy density at the surface of the polycrystalline semiconductor layer falls within a range from 200 mJ/cm² or greater to 450 mJ/cm² or smaller. Specifically, a XeCl excimer laser beam having a wavelength of 308 nm, a KrF excimer laser bear having a wavelength of 248 nm, and the like are preferable. In addition, at least one selected from the group consisting of the second harmonic of Nd:YAG laser, the second harmonic of Nd:YVO₄ laser, the second harmonic of Nd:YLF laser, the second harmonic of Nd:glass laser, the second harmonic Yb:YAG laser, the second harmonic of Yb:glass laser, Ar ion laser, the second harmonic of Ti:sapphire laser, and Dye laser may be included.

The laser crystallization process using such a laser crystallization device is carried out as follows. First, the insulating substrate 11 having thereon the amorphous silicon thin film 29 formed is placed on the work stage of the laser crystallization device. By transmitting a signal from the system controller, a pulsed laser beam is oscillated from a laser beam source of the pulsed laser oscillator.

Next, the oscillated pulsed laser beam is reflected off the mirror and directed to the optical system. By the optical system, the oscillated pulsed laser beam is shaped to be a laser beam, with which the amorphous silicon thin film 29 is irradiated.

After the amorphous silicon thin film 29 is irradiated with the laser beam, the work stage is moved in the plane direction by the system controller, such that the amorphous silicon thin film 29 is crystallized successively from one end portion toward the other end portion. In this manner, the amorphous silicon thin film 29 is poly-crystallized.

Because the amorphous silicon thin film 29 formed on the insulating layer 13 that is elevated on the stepwise layer 12 is similarly elevated at the corresponding portion, when the amorphous silicon thin film 29 is crystallized successively from one end toward the other end by the laser beam, step-caused disconnections occur at the locations corresponding to the end portions of the stepwise layer 12 of the amorphous silicon thin film 29. By the occurrence of the step-caused disconnections, poly-crystallized first semiconductor layers 14 are formed at the portions adjacent to the elevated insulating layer 13, and a poly-crystallized second semiconductor layer 14′ of an island shape is formed on the elevated insulating layer 13 as shown in FIG. 1.

At this timing, even in a case where a residue being the continuation of the amorphous silicon thin film 29 exists between the regions where the adjacent thin film transistors 17 and 18 are respectively formed before crystallizing the amorphous silicon thin film 29, the occurrence of the step-caused disconnections at the elevated insulating layer 13 as shown in FIG. 1 leaves just a non-continuous residue 14″, whereby a leak fault is successfully suppressed.

Further, in the above-described laser crystallization process, the portion having already been irradiated with the laser beam may again irradiated with the laser beam. This causes the step-caused disconnections of the semiconductor layer to occur in a further successful manner.

Next, pattern formation of the poly-crystallized first semiconductor layers 14 generated at the portions adjacent to the elevated insulating layer 13 is carried out by photolithography or the like.

Note that the above-described laser crystallization process may be carried out either before or after the pattern formation of the first semiconductor layers 14. Either way, the result is the same.

Subsequently, using the first semiconductor layers 14 as active layers, the thin film transistors 17 and 18 are formed.

Specifically, first, on the insulating layer 13, a gate insulating film 15 is deposited so as to cover the first semiconductor layers 14 and the second semiconductor layer 14′.

Next, a mask is formed on each of the first semiconductor layers 14 at a portion corresponding to a portion where a channel region is to be formed. Then, ion-implantation of an impurity element is carried out, such that, within each of the first semiconductor layers 14, an active layer structured with a channel region and low-concentration impurity regions (a source region and a drain region) on opposite sides thereof is formed.

Subsequently, the mask is removed, and as shown in FIG. 4, gate electrodes 19 and 20 are patterned by photolithography on the channel regions of the first semiconductor layers 14.

Next, after covering the gate insulating film 15 and the gate electrodes 19 and 20 by an interlayer insulating film 16, contact holes 25 to 28 are formed so as to extend from the surface of the interlayer insulating film 16, to penetrate through the interlayer insulating film 16 and the gate insulating film 15, and to reach the source region and the drain region of each of the first semiconductor layers 14.

Next, the contact holes 25 to 28 are each filled with a conductive material, so as to form source electrodes 21 and 23 and drain electrodes 22 and 24.

By providing the active matrix substrate formed in the above-described manner with a counter substrate, e.g., having a display medium layer interposed therebetween, the semiconductor device 10 such as a display device is completed.

### Operation and Effect of First Embodiment

In the first embodiment of the present invention, in the active matrix substrate having the pixel regions disposed in a matrix pattern, the stepwise layer 12 whose end portions each previously have an inclination angle A of equal to or greater than 60° is formed so as to extend between the formation regions of the thin film transistors 17 and 18 of adjacent respective pixel regions. Then, the insulating layer 13 is arranged so as to be elevated on the stepwise layer 12, and the amorphous silicon thin film 29 is formed on the insulating layer 13. Thereafter, silicon thin film crystallization is carried out by laser beam irradiation. This causes the step-caused disconnections to occur at portions where the covering ability of the silicon thin film is weakened due to the great inclination angle A. This makes it possible to successfully suppress, between the adjacent thin film transistors 17 and 18, generation of a residue being the continuation of the semiconductor layer between the semiconductor layers 14 respectively structuring the adjacent thin film transistors 17 and 18, without using photolithography or the like. Hence, it becomes possible to effectively suppress occurrence of a leak fault due to an electric connection established between the thin film transistors 17 and 18 by the residue being the continuation of the semiconductor layer. Further, because the crystallization of the silicon thin film and the patterning for the purpose of preventing a leak fault can be carried out simultaneously and accurately, an excellent manufacturing efficiency can be achieved.

Still further, because the insulating layer 13 has a thickness of equal to or greater than 20 nm, an excellent insulation can be achieved. Still further, because the insulating layer 13 has a thickness of equal to or smaller than 200 nm, it is successfully affected by the angle of each end portion of the stepwise layer 12, resulting in easier occurrence of the step-caused disconnections.

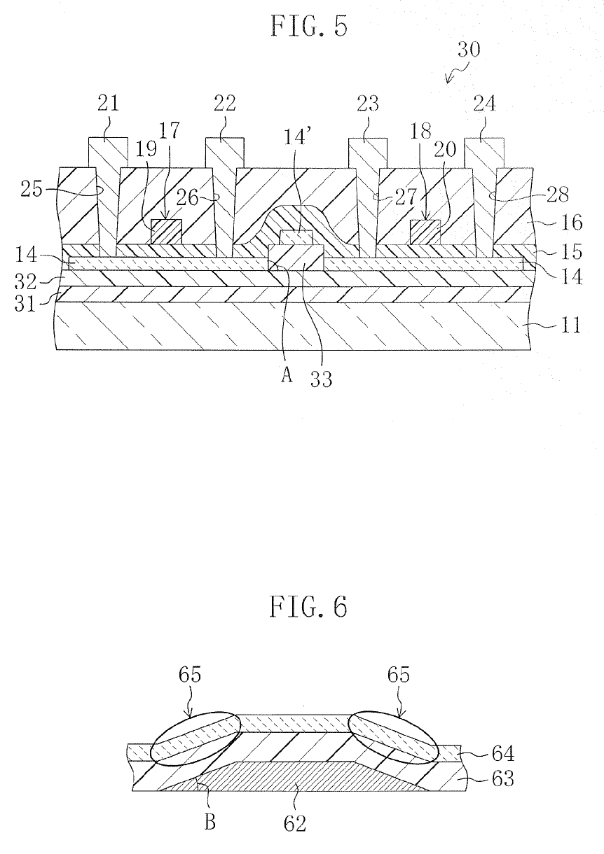

It is noted that, the configuration of arranging the stepwise layer between the thin film transistors of the semiconductor device, such that, as described above, the step-caused disconnections occur by the laser crystallization process is not limited, to the foregoing mode. For example, another possible configuration may be the one shown in FIG. 5. Specifically, a semiconductor device 30 shown in FIG. 5 is different from the semiconductor device 10 having the structure shown in FIG. 2 in that a second semiconductor layer 14′ is directly formed on a stepwise layer 33. Note that constituent elements shown in FIG. 5 similar to those shown in FIG. 2 are denoted by the same reference numbers, and description thereof is omitted.

The manufacturing method of the semiconductor device shown in FIG. 5 is as follows. First, on an insulating substrate 11 such as a glass substrate, base coat layers 31 and 32 are formed. The base coat layers 31 and 32 may be formed by, for example, SiN, SiO₂ or the like. The base coat layers are not necessarily structured by two layers as shown in FIG. 5, but instead, may be structured by one layer or three or more layers.

Subsequently, on the base coat layer 32, a stepwise layer 33 structured with, for example, SiN, SiO₂ or the like is formed. The stepwise layer 33 may be formed by etching newly deposited another member being different from the base coat layer 32. Alternatively, the stepwise layer 33 may be formed by etching only the upper portion of the base coat layer 32. In this case, the base coat layer 32 and the stepwise layer 33 are integrally formed. Additionally, the stepwise layer 33 is formed so as to extend between adjacent thin film transistors 17 and 18 of the semiconductor device 30, and to have end portions each having an inclination angle A of equal to or greater than 60°.

Next, after an amorphous silicon thin film is formed on the stepwise layer 33 and the base coat layer 32, silicon thin film crystallization is carried out by laser beam radiation, thereby causing step-caused disconnections to occur at the portions corresponding to the end portions of the stepwise layer 33 where the covering ability of the silicon thin film is weakened. Similarly to the semiconductor device 10 shown in FIGS. 1 and 2, this makes it possible to successfully suppress, between the adjacent thin film transistors 17 and 18, generation of a residue being the continuation of the semiconductor layer between the semiconductor layers 14 respectively structuring the adjacent thin film transistors 17 and 18, without using photolithography or the like. Hence, it becomes possible to effectively suppress occurrence of a leak fault due to an electric connection established between the thin film transistors 17 and 18 by the residue being the continuation of the semiconductor layer.

### Example

An evaluation test was conducted to see the step-caused disconnection state in connection with the relationship between the inclination angle A of the end portion of the stepwise layer and the thickness of the insulating layer between the stepwise layer and the silicon thin film. In the present evaluation test, a process similarly to the laser beam radiation carried out in the manufacturing method of the semiconductor device 10 described in the first embodiment. Specifically, nine types of stepwise layers whose end portions respectively having different inclination angles A of 10 to 90° were each formed on an insulating substrate, which were then each provided thereon with insulating layers having different thicknesses of 20 to 100 nm. Further, on each of the insulating layers, amorphous silicon thin film was formed, and the crystallization process was carried out by laser beam irradiation. Table 1 shows the result. In Table 1, ◯ represents that no step-caused disconnections occurred. Δ represents that the step-caused disconnections partially occurred. X represents that step-caused disconnections fully occurred, and that no residue by which the silicon layer became continuous was generated.

TABLE 1

| | | thickness of insulating layer (mm) | | | | |
|---|---|---|---|---|---|---|
| | | 20 | 40 | 60 | 80 | 100 |
| inclina- | 10 | ◯ | ◯ | ◯ | ◯ | ◯ |
| tion | 20 | ◯ | ◯ | ◯ | ◯ | ◯ |
| angle | 30 | ◯ | ◯ | ◯ | ◯ | ◯ |
| (deg) | 40 | Δ | Δ | Δ | Δ | ◯ |
| | 50 | X | X | Δ | Δ | Δ |
| | 60 | X | X | X | X | X |
| | 70 | X | X | X | X | X |
| | 80 | X | X | X | X | X |
| | 90 | X | X | X | X | X |

Referring to Table 1, it can be seen that the step-caused disconnections successfully occurred irrespective of the thickness of the insulating layer, in the cases where the inclination angle A at each end portion of the stepwise layer was equal to or greater than 60°.

On the other hand, in the cases where the inclination angle A at each end portion of the stepwise layer is smaller than 60°, the step-caused disconnections did not fully occur, and some left a residue or the like. The reason therefor is explained as follows. As shown FIG. 6, when an inclination angle B at each end portion of the stepwise layer 62 is smaller than 60°, covering ability of the silicon thin film 64 formed on the insulating layer 63 relative to the insulating layer 63 formed to be elevated on the stepwise layer 62 is enhanced, which hinders the occurrence of the step-caused disconnections at the inclination portion 65.

### Second Embodiment

Next, the structure of a semiconductor device 40 in accordance with a second embodiment of the present invention will be described.

### (Structure of Semiconductor Device 40)

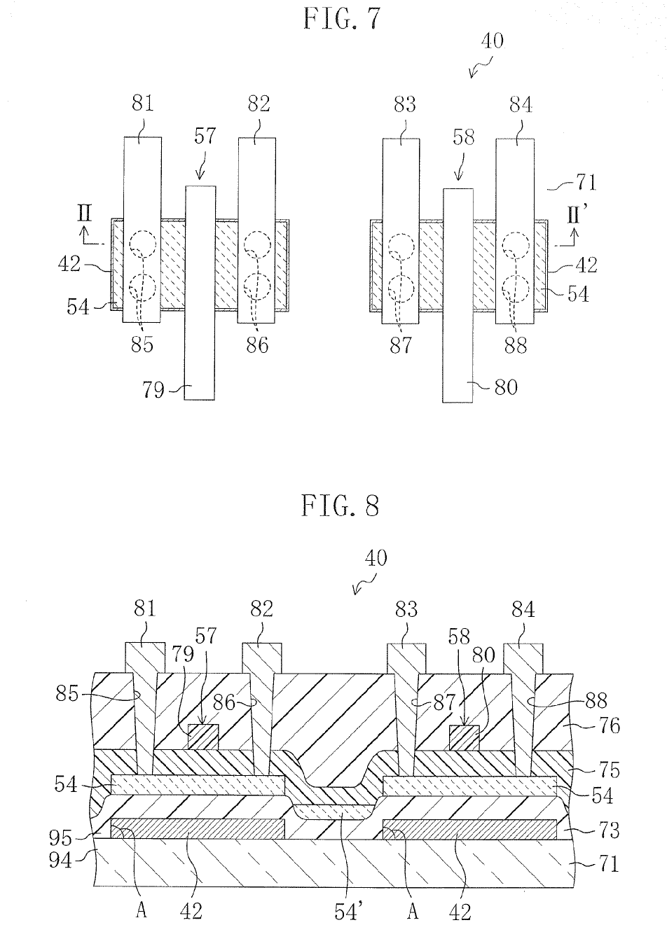

FIG. 7 is a schematic plan view of an active matrix substrate of the semiconductor device 40 in accordance with the second embodiment of the present invention. FIG. 8 is a cross-sectional view taken along line II-II′ in FIG. 7.

The semiconductor device 40 includes the active matrix substrate shown in FIGS. 7 and 8. The active matrix substrate includes an insulating substrate 71 such as a glass substrate. Formed on the insulating substrate 71 are stepwise layers 42 corresponding to second semiconductor layers 54 that are formed at respective pixel regions that are disposed in a matrix pattern.

An inclination angle A at each end portion of the stepwise layers 42 is formed to be approximately 90°. Here, the inclination angle A of equal to or greater than 60° suffices for each end portion of the stepwise layers 42. For example, each end portion of the stepwise layers 42 may be greater than 90°. In other words, each end portion of the stepwise layers 42 may be formed in an inverse tapered shape. In the present embodiment, the stepwise layers 42 are formed by a light-shielding material that is structured with any high melting point metal such as Mo, for example. That is, the stepwise layers 42 structure light shielding layers for thin film transistors 57 and 58 arranged above them in the semiconductor device 40. It is noted that, when it is not necessary to arrange any light shield layer below the thin film transistors 57 and 58, the stepwise layers 42 may be formed by a material not possessing the light-shielding property. For example, the stepwise layers 42 may preferably be formed by insulating layers.

On the insulating substrate 71 and the stepwise layers 42, an insulating layer 73 is formed. The insulating layer 73 is formed to have a thickness of equal to or greater than 20 nm and equal to or smaller than 200 nm, and arranged to be elevated on the stepwise layers 42.

On the insulating layer 73, the thin film transistors 57 and 58 are formed. The thin film transistors 57 and 58 each function as a switching element of corresponding pixel region, and respectively include second semiconductor layers 54 each having an active layer and structured with polycrystalline silicon, and gate electrodes 79 and 80 formed on the second semiconductor layers 54 each having a gate insulating film 75 interposed therebetween. The second semiconductor layers 54 are each formed in an island shape on the insulating layer 73 that is elevated on the stepwise layers 42. Each active layer includes a channel region, and a source region and a drain region arranged on opposite sides of the channel region.

The first semiconductor layer 54′ is arranged at a portion adjacent to the portions of the insulating layer 73 that are elevated on the stepwise layers 42. The first semiconductor layer 54′ is structured with a material identical to that of the second semiconductor layers 54, that is, with polycrystalline silicon.

On the thin film transistors 57 and 58, an interlayer insulating film 76 is formed. At the interlayer insulating film 76 and the gate insulating film 75, contact holes 85 to 88 that reach the source region and the drain region of each of the active layers of each of the thin film transistors 57 and 58 are formed. The contact holes 85 and 87 that reach the source regions of the active layers and the contact holes 86 and 88 that reach the drain regions of the active layers are each filled with a conductive material, thereby structuring source electrodes 81 and 83 and drain electrodes 82 and 84, respectively.

The semiconductor device 40 preferably includes a mechanism configured to fix the potential of the stepwise layers 42 to a prescribed value, in a case where the stepwise layers 42 are formed by conductive layers. For example, the semiconductor device 40 includes a grounding mechanism configured to electrically ground the stepwise layers 42. Another possible configuration is to connect the stepwise layers 42 to a voltage source that maintains the potential of the stepwise layers 42 at a prescribed value.

The semiconductor device 40 includes the active matrix substrate structured as described above, and additionally provided with a display medium layer and the like. In this manner, the semiconductor device 40 structures, for example, a display device such as a liquid crystal display device, an organic/inorganic EL display device and the like.

### (Manufacturing Method of Semiconductor Device 40)

Next, a manufacturing method of the semiconductor device 40 in accordance with the second embodiment of the present invention will be described.

First, an insulating substrate 71 such as a glass substrate is prepared. On the insulating substrate 71, a light-shielding material is deposited, which is structured with a high melting point metal such as Mo, for example. Thereafter, by carrying out etching, stepwise layers 42 having a thickness of, for example, equal to or greater than 50 nm and end portions each having an inclination angle A of 90° is formed at regions corresponding to thin film transistors 57 and 58. Note that the stepwise layers 42 may be formed by insulating layers instead of any high melting point metal such as described above.

Next, on the insulating substrate 71 and the stepwise layers 42, an insulating layer 73 having a thickness of equal to or greater than 20 nm and equal to or smaller than 200 nm is formed. Here, the insulating layer 73 is formed so as to be elevated on the stepwise layers 42 relative to the other portion.

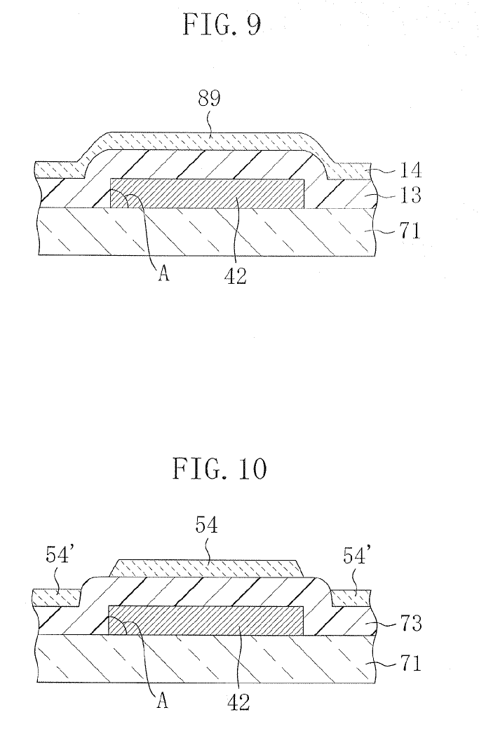

Subsequently, on the insulating layer 73 formed on the insulating substrate 71 and the stepwise layers 42, as shown in FIG. 9, an amorphous silicon thin film 89 is formed.

Next, the amorphous silicon thin film 89 is subjected to a laser crystallization process. In carrying out the laser crystallization process, a laser crystallization device similarly to that used in the first embodiment is used. The laser crystallization process is carried out as follows. First, the insulating substrate 71 having thereon the amorphous silicon thin film 89 formed is placed on the work stage of the laser crystallization device. By transmitting a signal from the system controller, a pulsed laser beam is oscillated from a laser beam source of the pulsed laser oscillator.

Next, the oscillated pulsed laser beam is reflected off the mirror and directed to the optical system. By the optical system, the oscillated pulsed laser beam is shaped to be a laser beam, with which the amorphous silicon thin film 89 is irradiated.

After the amorphous silicon thin film 89 is irradiated with the laser beam, the work stage is moved in the plane direction by the system controller, such that the amorphous silicon thin film 89 is crystallized successively from one end portion toward the other end portion. In this manner, the amorphous silicon thin film 89 is poly-crystallized.

Because the amorphous silicon thin film 89 formed on the insulating layer 73 that is elevated on the stepwise layers 42 is similarly elevated at the corresponding portions, when the amorphous silicon thin film 89 is crystallized successively from one end toward the other end by the laser beam, as shown in FIG. 10, step-caused disconnections occur at the locations corresponding to the end portions of each stepwise layer 42 of the amorphous silicon thin film 89. By the occurrence of the step-caused disconnections, a poly-crystallized first semiconductor layer 54′ is formed at the portion adjacent to the elevated insulating layer 73, and island-shaped second semiconductor layers 54 are formed on the elevated insulating layer 73.

At this timing, the portion having already been irradiated with laser beam may again irradiated with laser beam. This causes the step-caused disconnection of the semiconductor layer to occur in a further successful manner.

Next, using the second semiconductor layers 54 formed by the occurrence of the step-caused disconnections as active layers, the thin film transistors 57 and 58 are formed.

Specifically, first, on the insulating layer 73, a gate insulating film 75 is deposited so as to cover the first semiconductor layer 54′ and the second semiconductor layers 54.

Next, a mask is formed on each of the second semiconductor layers 54 at a portion corresponding to a portion where a channel region is to be formed. Then, ion-implantation of impurity element is carried out, such that, within each of the second semiconductor layers 54, an active layer structured with a channel region and low-concentration impurity regions (a source region and a drain region) on opposite sides thereof is formed.

Subsequently, the mask is removed, and, gate electrodes 79 and 80 are patterned by photolithography on the channel regions of the second semiconductor layers 54.

Next, after covering the gate insulating film 75 and the gate electrodes 79 and 80 by an interlayer insulating film 76, contact holes 85 to 88 are formed so as to extend from the surface of the interlayer insulating film 76, to penetrate through the interlayer insulating film 76 and the gate insulating film 75, and to reach the source region and the drain region of each of the second semiconductor layers 54.

Next, the contact holes 85 to 88 are each filled with a conductive material, so as to form source electrodes 81 and 83 and drain electrodes 82 and 84.

By providing the active matrix substrate formed in the above-described manner with a counter substrate, e.g., having a display medium layer interposed therebetween, the semiconductor device 40 such as a display device is completed.

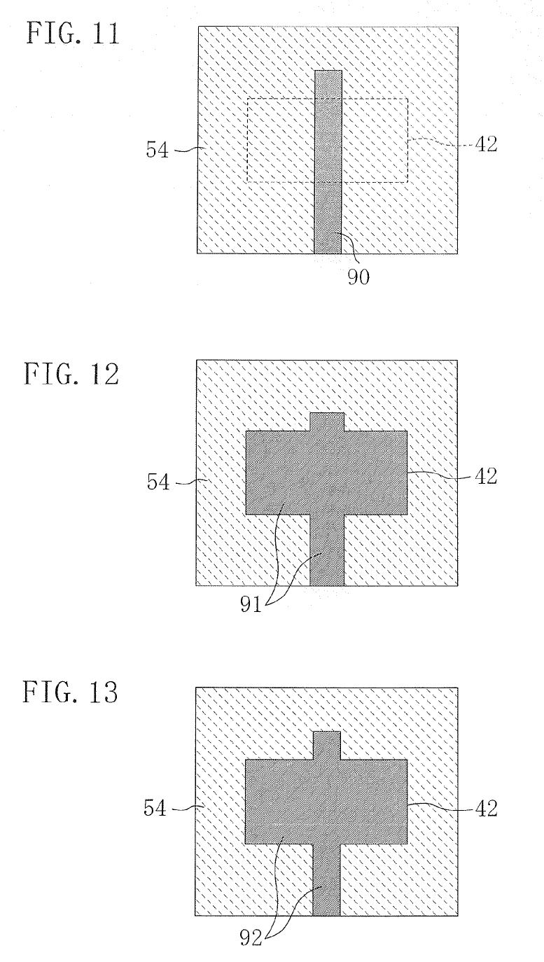

Further, as described in the foregoing, in pattering the second semiconductor layers 54, use of the stepwise layers 42 arranged below whose end portions each have an inclination angle A of equal to or greater than 60° successfully reduces the mask region of the semiconductor layer in the formation step of the thin film transistors 57 and 58. This principle will be described in detail, showing an exemplary case where an N channel type polycrystalline silicon thin film transistor is formed in one of the adjacent second semiconductor layers 54, and a P channel type polycrystalline silicon thin film transistor is formed in the other one. The manufacturing steps of the N channel type polycrystalline silicon thin film transistor are shown in FIGS. 11, 13 and 15, and the manufacturing steps of the P channel type polycrystalline silicon thin film transistor are shown in FIGS. 12, 14 and 16.

FIGS. 11 and 12 show a structure obtained as follows. By carrying out a laser beam radiation to an amorphous silicon thin film provided with stepwise layers 42 below, the end portions of the stepwise layers 42 each having an inclination angle A of equal to or greater than 60°, in a manner described above, the amorphous silicon thin film is crystallized. By doing so, the step-caused disconnections occur and thereby the patterning is achieved. Here, as to the second semiconductor layer 54 where an N channel type polycrystalline silicon thin film transistor is formed, a mask 90 is formed at a gate electrode formation region, as shown in FIG. 11. As to the second semiconductor layer 54 where a P channel type polycrystalline silicon thin film transistor is formed, a mask 91 is provided at a gate electrode formation region and on an island-shaped second semiconductor layer 54, as shown in FIG. 12. Because the mask 91 is arranged on the accurately patterned second semiconductor layer 54, it is not necessary to allow a margin and to form the mask 91 greater than needed.

Next, an N channel impurity is implanted to the second semiconductor layers 54 to form an active layer of the N channel type polycrystalline silicon thin film transistor. Then, the masks 90 and 91 shown in FIGS. 11 and 12 are removed.

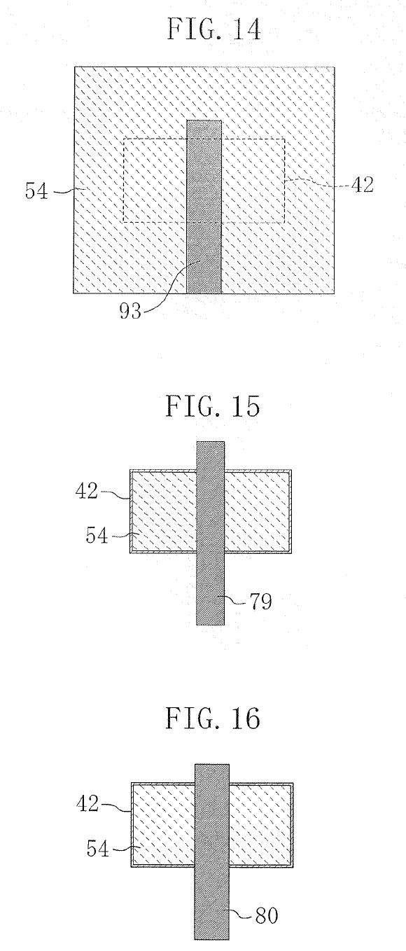

Subsequently, on the second semiconductor layer 54 and at the gate electrode formation region where the N channel type polycrystalline silicon thin film transistor is formed is provided with a mask 92 as shown in FIG. 13, and the second semiconductor layer 54 where the P channel type polycrystalline silicon thin film transistor is formed is provided with a mask 93 at the gate electrode formation region as shown in FIG. 14. In such a state, a P channel impurity is implanted to form an active layer of the P channel type polycrystalline silicon thin film transistor. Again, the mask 92 formed as shown in FIG. 13 is arranged on the accurately patterned second semiconductor layer 54, it is not necessary to allow a margin and to form the mask 92 greater than needed.

Next, the masks 92 and 93 shown in FIGS. 13 and 14 are removed to form gate electrodes 79 and 80. Thus, the N channel type polycrystalline silicon thin film transistor shown in FIG. 15 and the P channel type polycrystalline silicon thin film transistor shown in FIG. 16 are fabricated.

Note that, as shown in FIG. 8, as a result of the step-caused disconnection processing by the laser beam, a first semiconductor layer 54′ is formed at a portion adjacent to the insulating layer 73 elevated on the stepwise layer 42. If such a first semiconductor layer 54′ is located at the transmitting portion of the panel, it may be removed by photolithography, etching or the like in the above-described formation step of the thin film transistors 57 and 58.

### Operation and Effect of Second Embodiment

In accordance with the second embodiment of the present invention, the insulating layer 73 is arrange so as to be elevated on the stepwise layers 42 whose end portions each have an inclination angle A of equal to or greater than 60°, and the amorphous silicon thin film is formed on the insulating layer 73. Thereafter, silicon thin film crystallization is carried out by laser beam radiation. Accordingly, because the inclination angle A is great, step-caused disconnections occur at the portions where covering ability of the silicon thin film is weakened. This makes it possible to accurately pattern the silicon thin film without using photolithography or the like. Further, because the crystallization and the patterning of the silicon thin film can be carried out simultaneously, an excellent manufacturing efficiency can be achieved.

Still further, because the insulating layer 73 has a thickness of equal to or greater than 20 nm, an excellent insulation can be achieved. Still further because the insulating layer 73 has a thickness of equal to or smaller than 200 nm, it is successfully affected by the angle of each end portion of the stepwise layers 42, resulting in easier occurrence of the step-caused disconnections.

Still further, because the stepwise layers (light shielding layers) 42 arranged below the second semiconductor layers 54 each have a thickness of equal to or greater than 50 nm, the stepwise layers (light shielding layers) 42 successfully shield the thin film transistors 57 and 58 against transmission of light. This successfully suppresses a reduction in the device quality of the semiconductor device 40.

Because use of the island-shaped layers formed on the elevated insulating layer 73 as the active layers of the thin film transistors 57 and 58 achieves accurate patterning of the silicon thin film, it is not necessary to form the stepwise layers (light shielding layers) 42 arranged below to be greater in size than needed. Therefore, the aperture ratio of the semiconductor device 40 is improved.

Further, in patterning the second semiconductor layers 54, use of the stepwise layers 42 arranged below whose end portions each have an inclination angle A of equal to or greater than 60° successfully reduces the mask region of the semiconductor layer in the formation step of the thin film transistors 57 and 58.

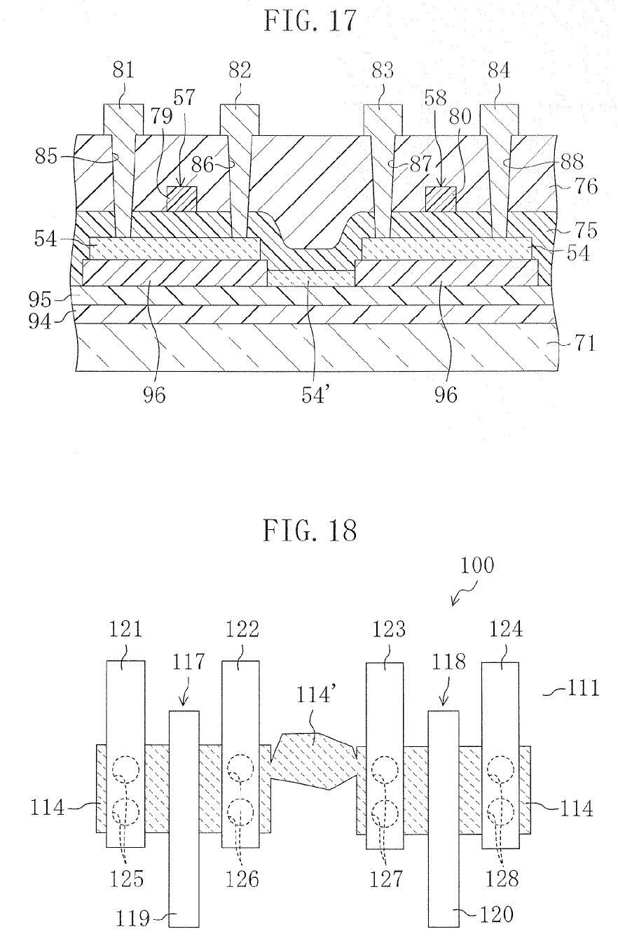

It is noted that, the configuration of arranging the stepwise layers below the active layers of the thin film transistors of the semiconductor device, such that, as described above, the step-caused disconnections occur in the laser crystallization process is not limited to the foregoing mode. For example, another possible configuration may be the one shown in FIG. 17.

Specifically, a semiconductor device 70 shown in FIG. 17 is different from the semiconductor device 40 having the structure shown in FIG. 8 in that second semiconductor layers 54 are directly formed on stepwise layers 96. Note that constituent elements shown in FIG. 17 similar to those shown in FIG. 8 are denoted by the same reference numbers, and description thereof is omitted.

The manufacturing method of the semiconductor device 70 shown in FIG. 17 is as follows. First, on an insulating substrate 71 such as a glass substrate, base coat layers 94 and 95 are formed. The base coat layers 94 and 95 may be formed by, for example, SiN, SiO₂ or the like. The base coat layer are not necessarily structured by two layers as shown in FIG. 17, but instead, may be structured by one layer or three or more layers.

Subsequently, on the base coat layer 95, stepwise layers 96 structured with, for example, SiN, SiO₂ or the like are formed. The stepwise layers 96 may be formed by etching newly deposited another member being different from the base coat layer 95. Alternatively, the stepwise layers 96 may be formed by etching only the upper portion of the base coat layer 95. In this case, the base coat layer 95 and the stepwise layers 96 are integrally formed. Additionally, the stepwise layers 96 are formed so as to extend between adjacent thin film transistors 57 and 58, and to have end portions each having an inclination angle A of equal to or greater than 60°.

Next, after an amorphous silicon thin film is formed on the stepwise layers 96 and the base coat layer 95, silicon thin film crystallization is carried out by laser beam radiation, thereby causing step-caused disconnections to occur at the portions corresponding to the end portions of the stepwise layers 96 where the covering ability of the silicon thin film is weakened.

Next, similarly to the above-described semiconductor device 40, using the second semiconductor layers 54 formed by the occurrence of the step-caused disconnections as active layers, the thin film transistors 57 and 58 are formed. Here, as shown in FIG. 17, a first semiconductor layer 54′ is formed at a portion adjacent to the stepwise layers 96 as a result of the step-caused disconnection processing by the laser beam. If such a first semiconductor layer 54′ is located at the transmitting portion of the panel, it may be removed by photolithography, etching or the like in the formation step of the thin film transistors 57 and 58.

Hence, it becomes possible to accurately and easily pattern the semiconductor layers 54 that structure the active layers of the thin film transistors 57 and 58, without using photolithography or the like.

### INDUSTRIAL APPLICABILITY

As described in the foregoing, the present invention is useful to a semiconductor device and a method for manufacturing the same, which are applied to liquid crystal display device, for example, of an active matrix type and the like.

### DESCRIPTION OF REFERENCE CHARACTERS

10, 30, 40, 70 Semiconductor Device
11, 71 Insulating Substrate
12, 33, 42, 96 Stepwise Layer
13, 73 Insulating Layer
14, 54′ First Semiconductor Layer
14′, 54 Second Semiconductor Layer
17, 18, 57, 58 Thin Film Transistor
31, 32, 94, 95 Base Coat Layer

1. A semiconductor device, comprising:
an insulating substrate;
a stepwise layer arranged on the insulating substrate and having an end portion whose inclination angle is equal to or greater than 60°;
an insulating layer formed on the insulating substrate and the stepwise layer so as to be elevated on the stepwise layer;
a first semiconductor layer arranged at a portion adjacent to the elevated insulating layer; and
a second semiconductor layer structured with a material identical to a material of the first semiconductor layer, and formed in an island shape on the elevated insulating layer.

2. The semiconductor device according to claim 1, wherein
the insulating layer has a thickness of equal to or greater than 20 nm and equal to or smaller than 200 nm.

3. The semiconductor device according to claim 1, wherein
the stepwise layer is a light shielding layer.

4. The semiconductor device according to claim 3, wherein
the light shielding layer has a thickness of equal to or greater than 50 nm.

5. A semiconductor device, comprising:
an insulating substrate;
a base coat layer arranged on the insulating substrate;
a stepwise layer arranged on the base coat layer and having an end portion whose inclination angle is equal to or greater than 60°;
a first semiconductor layer arranged on the base coat layer and at a portion adjacent to the stepwise layer; and
a second semiconductor layer structured with a material identical to a material of the first semiconductor layer, and formed in an island shape on the stepwise layer.

6. The semiconductor device according to claim 1, wherein
the first semiconductor layer is provided at least two in number so as to be disposed adjacent to each other, each of the first semiconductor layers structuring an active layer of a thin film transistor; and
the second semiconductor layer is arranged between the adjacent first semiconductor layers.

7. The semiconductor device according to claim 1, wherein
the second semiconductor layer structures an active layer of a thin film transistor.

8. The semiconductor device according to claim 7, wherein
the stepwise layer is structured with an insulating layer.

9. The semiconductor device according to claim 7, wherein
the stepwise layer is structured with a conductive layer, the semiconductor device further comprising:
a mechanism configured to fix a potential of the stepwise layer to a prescribed value.

10. A method for manufacturing a semiconductor device, comprising:
a stepwise layer formation step of forming a stepwise layer having an end portion whose inclination angle is equal to or greater than 60° on an insulating substrate;
an insulating layer formation step of forming an insulating layer on the insulating substrate and the stepwise layer so as to be elevated on the stepwise layer;
a semiconductor layer formation step of forming a semiconductor layer on the insulating layer formed on the insulating substrate and the stepwise layer; and
a step-caused disconnection formation step of irradiating the semiconductor layer with a laser beam so as to crystallize the semiconductor layer and to form a step-caused disconnection at the semiconductor layer at a portion corresponding to the end portion of the stepwise layer, thereby forming a first semiconductor layer at a portion adjacent to the elevated insulating layer, and an island-shaped second semiconductor layer on the elevated insulating layer.

11. The method for manufacturing a semiconductor device according to claim 10, wherein
in the insulating layer formation step, the insulating layer is formed to have a thickness of equal to or greater than 20 nm and equal to or smaller than 200 nm.

12. The method for manufacturing a semiconductor device according to claim 10, wherein
the stepwise layer is a light shielding layer.

13. The method for manufacturing a semiconductor device according to claim 12, wherein
the light shielding layer is formed to have a thickness of equal to or greater than 50 nm.

14. A method for manufacturing a semiconductor device, comprising:
a stepwise layer formation step of forming a stepwise layer having an end portion whose inclination angle is equal to or greater than 60° on a base coat layer, the base coat layer being formed on a surface of an insulating substrate;
a semiconductor layer formation step of forming a semiconductor layer on the base coat layer and the stepwise layer so as to be elevated on the stepwise layer; and
a step-caused disconnection formation step of irradiating the semiconductor layer with a laser beam so as to crystallize the semiconductor layer and to form a step-caused disconnection at the semiconductor layer at a portion corresponding to the end portion of the stepwise layer, thereby forming a first semiconductor layer at a portion adjacent to the stepwise layer, and an island-shaped second semiconductor layer on the stepwise layer.

15. The method for manufacturing a semiconductor device according to claim 10, wherein
the first semiconductor layer formed in the step-caused disconnection formation step is used as an active layer to form a thin film transistor.

16. The method for manufacturing a semiconductor device according to claim 10, wherein
the second semiconductor layer formed in the step-caused disconnection formation step is used as an active layer to form a thin film transistor.

17. The method for manufacturing a semiconductor device according to claim 16, wherein
the stepwise layer is structured with an insulating layer.
